(19) United States
(12) Patent Application Publication
(10) Pub. No.: US 2005/0093638 A1
(43) Pub. Date: May 5, 2005

(54) Methods and apparatus to control frequency offsets in digitally controlled crystal oscillators

(76) Inventors: Heng-Chih Lin, Plano, TX (US); Chien-Chung Chen, Plano, TX (US); Dirk Leipold, Plano, TX (US)

Correspondence Address: TEXAS INSTRUMENTS INCORPORATED, P O BOX 655474, M/S 3999, DALLAS, TX, 75265, US

(21) Appl. No.: 10/966,220

(22) Filed: Oct. 15, 2004

Related U.S. Application Data
(60) Provisional application No. 60/517,119, filed on Nov. 3, 2003.

(51) Int. Cl. H03L 1/00; H03B 1/00

(52) U.S. Cl. 331/176

(57) ABSTRACT

Methods and systems of adjusting an oscillator frequency are disclosed. One example method includes reading a temperature associated with an oscillator, reading a first tuning code associated with the temperature from a memory, and tuning the oscillator with the first tuning code. The example method may further include determining a second tuning code, and storing the second tuning code and an indication of the temperature in the memory.

### CROSS REFERENCE TO RELATED APPLICATIONS

This application incorporates by reference and claims the benefit of U.S. Provisional Application No. 60/517,119, filed Nov. 3, 2003.

### TECHNICAL FIELD

The present disclosure pertains to oscillator frequency control and, more particularly, to methods and apparatus to control frequency offsets in digitally controlled crystal oscillators.

### BACKGROUND

As will be readily appreciated, crystal oscillators or crystals, which are found in many electrical circuits, are devices that are fabricated to resonate at predefined frequencies in response to applied voltages. For example, the ubiquitous color burst crystal resonates at a frequency of 3.57954 megahertz (MHz) and may be found in almost every television and radio manufactured.

Many systems and circuits utilize crystal oscillators to provide a clock reference representative of relative time. For example, microprocessors and microcontrollers typically utilize crystal oscillators to derive system clocks that control the rate at which data is read by input/output ports and/or the rate at which programming instructions are executed.

Communication systems and components such as telecommunications infrastructure and mobile units use crystal oscillators to generate one or more frequencies that are useful in producing radio frequency (RF) signals onto which information to be broadcast and received is imparted. For example, a crystal oscillator is usually used to generate a master reference clock that is used to synchronize information exchange between telecommunications infrastructure and mobile units.

Crystal oscillators all have tolerance ranges associated with their resonant frequency. The difference between the ideal resonant frequency of a crystal oscillator and the actual operating frequency of the crystal oscillator is referred to as the frequency offset of the crystal oscillator. For example, a crystal oscillator may be specified to have a tolerance between 10 parts-per-million (PPM) and 100 PPM at an operating temperature of 25° C. However, it is a rare situation in which a crystal oscillator is operated at the specified 25° C. temperature. Accordingly, in practice, the actual operational frequency of a crystal oscillator may vary outside the specified 25° C. tolerance. Therefore, there is almost always a frequency offset in a crystal oscillator.

Some applications, such as communications systems, require a high degree of crystal oscillator precision (i.e., very low frequency offset) to prevent interference with neighboring communication channels. To control more precisely the resonant frequency of a crystal oscillator, some communication systems utilize a digitally controlled crystal oscillator (DCXO) system in conjunction with a crystal. A DCXO system typically includes a processing portion that monitors the resonant frequency produced by a crystal oscillator and alters the resonant frequency of the crystal oscillator by outputting a code to a DCXO circuit that changes the capacitive loading on the crystal oscillator to tune the frequency of the crystal oscillator. The capacitive loading is typically achieved via one or more programmable capacitors having digital interfaces that accept the DCXO codes and change capacitance in response to the DCXO codes.

In practice, when a DCXO system is first powered up, such as when a mobile telephone is turned on, an initial DCXO code is used to set the loading capacitance of the crystal oscillator. The initial frequency output by the crystal needs only to be within a few PPM of the target frequency (i.e., a relatively large offset). After communication is established with another entity, fine frequency tuning may be carried out during which the DCXO changes its output code to refine the load capacitance and bring the resonant frequency within fractions of a PPM of the target frequency (i.e., to lower the offset).

Based on various environmental characteristics, such as process, voltage, and temperature (PVT) variations, the resonant frequency of a crystal oscillator may not meet the initial frequency accuracy of a few PPM under all conditions (i.e., the initial offset of the frequency system may be larger than desired). Therefore, many manufacturers calibrate a DCXO with an initial code for operation with a particular crystal oscillator at one specific temperature (e.g., 25° C.) and store the DCXO code associated with that crystal in memory, such as flash memory, before shipping the product. In the field, when the device attempts to establish initial communication, the DCXO code stored in memory is applied as a first attempt to load the crystal oscillator to achieve the desired oscillator frequency.

However, even when the pre-calibrated DCXO code is loaded, there is no guarantee that the ambient temperature of the crystal oscillator is the same as the calibration temperature at which the initial DCXO code was selected. Additionally, there is no guarantee that the temperature coefficient of the crystal, the supply voltage, and the DXCO circuit will not shift the frequency offset produced using the DCXO code to an unacceptable level. Further, as crystals age, their resonant frequencies may change, thereby potentially rendering the initial DCXO code ineffective.

In an attempt to improve the initial offset of the crystal oscillator caused by temperature, some manufacturers provide a temperature sensor associated with the DCXO and a fixed lookup table within a memory. The fixed lookup table stores a number of DCXO codes, each of which corresponds to a different sensed temperature. On system startup, the DCXO reads the temperature from the temperature sensor, retrieves from the fixed lookup table the DCXO code corresponding to the sensed temperature, and applies the retrieved DCXO code to initially calibrate the crystal oscillator. However, this solution does not account for crystal aging effects, temperature coefficient changes, or crystal replacement.

### BRIEF DESCRIPTION OF THE DRAWINGS

FIG. 1 is a diagram of an example communication system in which the disclosed frequency offset control systems and methods may be implemented.

FIG. 2 is a block diagram of an example disclosed frequency offset control system.

FIG. 3 is a schematic diagram of an example DCXO circuit.

FIG. 4 is a flow diagram of an example DCXO calibration process that may be carried out by the DCXO controller of FIG. 2.

FIG. 5 is a block diagram of an example implementation of the DCXO controller of FIG. 2.

### DETAILED DESCRIPTION

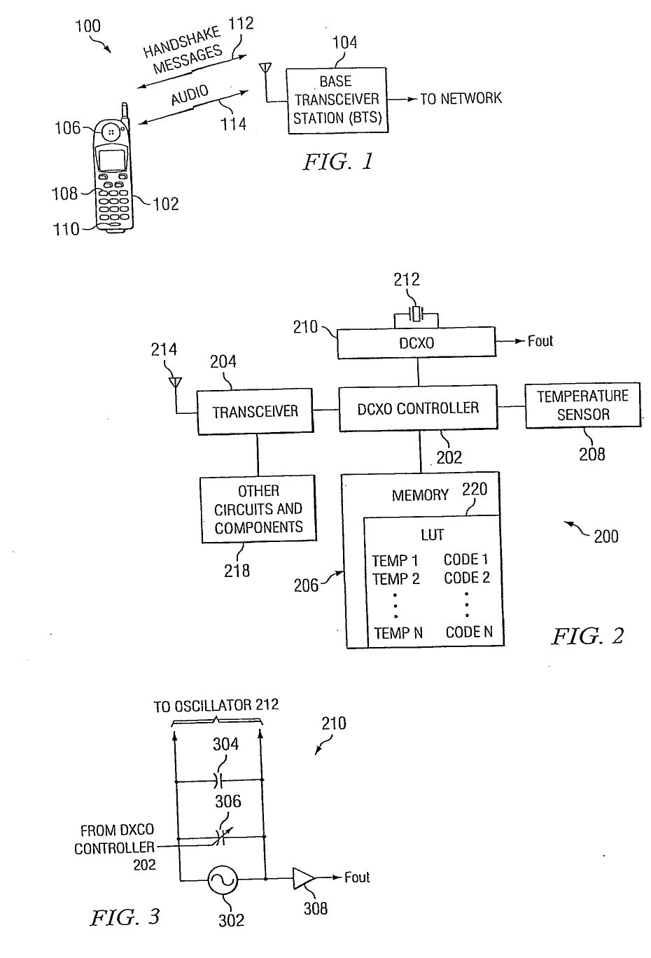

As shown in FIG. 1, an example communication system 100 in which the frequency offset control systems and methods disclosed herein may be used includes a mobile unit 102 and infrastructure 104. The mobile unit 102 may be implemented using a cellular telephone, such as a global system for mobile communications (GSM) telephone, or any other type of telephone that may operate under the principles of frequency division multiple access (FDMA), time-division multiple access (TDMA), and/or code-division multiple access (CDMA). For example, the mobile unit 102 may operate using the advance mobile phone service (AMPS), IS-95, IS-136, or any other suitable protocol. As will be readily appreciated by those having ordinary skill in the art, the mobile unit 102 may include an earpiece speaker 106, a keypad 108, and a microphone 110 in addition to numerous other components such as communications circuits. As described below, the mobile unit 102 may also include a frequency offset control system.

The infrastructure 104 may be implemented using a base transceiver station (BTS) that is configured for wireless communications with the mobile unit 102. The infrastructure 104 may be coupled to one or more other infrastructure units, the plain old telephone system (POTS), or any other suitable network. As with the mobile unit 102, the infrastructure 104 may be implemented as a GSM base station, or as any other FDMA, TDMA, or CDMA compatible base station. In the example of FIG. 1, the communication protocols used by the mobile unit 102 and the infrastructure 104 are not important to this disclosure. Of course, the communication protocols used by the mobile unit 102 and the infrastructure 104 must be compatible for information exchange to be carried out between the mobile unit 102 and the infrastructure 104.

As described below, the mobile unit 102 may initially calibrate its crystal oscillator using a DCXO system on power up. After initial crystal oscillator calibration, the mobile unit 102 establishes communications with the infrastructure 104 through the use of handshake messages 112. The handshake messages 112 may include the mobile unit 102 informing the infrastructure 104 of its presence in the area serviced by the infrastructure 104, or any other suitable communications required to make the mobile unit 102 and the infrastructure 104 compatible and ready to exchange voice and data over RF channels.

As part of the handshake messages 112 provided by the infrastructure 104, the infrastructure 104 provides a frequency control message to the mobile unit 102. For example, if the mobile unit 102 and the infrastructure 104 operate using the GSM protocol, the infrastructure provides the mobile unit 102 with a frequency control burst (FCB) on a frequency control channel (FCCH). In a known manner, the mobile unit 102 receives the FCB and calculates its frequency error. The DCXO system adjusts its DCXO code to tune the oscillator frequency accordingly.

After the handshake messages 112 complete, and the mobile unit 102 and the infrastructure 104 are configured to exchange information, audio messages 114 may be exchanged. As will be readily appreciated by those having ordinary skill in the art, in digital communication systems, the audio messages are exchanged as sequences of encoded symbols representing bits and bytes of information that are used to reconstruct the analog audio to be exchanged. Additionally, although reference has been made to audio messages, those having ordinary skill in the art will readily recognize that data messages, video messages, and/or any other types of messages maybe exchanged in the system 100 of FIG. 1.

Turning now to FIG. 2, a frequency offset control system 200, such as may be used in the mobile unit 102 or the infrastructure 104 of FIG. 1, is shown. At this point, it should be noted that while, for purposes of example and ease of understanding, the system 200 is described as being present within one or more of the components of the system 100, the system 200 could be used in any number of different applications. For example, the system 200 could be used in any system in which a low frequency offset at initial power up is desired. Such systems may include, control systems, other types of communications system, and virtually any circuit in which an oscillator is used.

As shown in FIG. 2, the system 200 includes a DCXO controller 202 to which a transceiver 204, a memory 206, a temperature sensor 208, and a DCXO circuit 210 are coupled. An oscillator 212 is coupled to the DCXO circuit 210. The oscillator 212 and the DCXO circuit 210 cooperate to produce an output frequency (Fout). The DCXO controller 202 adjusts the operation of the DCXO circuit 210 to control the output frequency (Fout) at startup of the mobile unit 102 in accordance with data stored in the memory 206 and a temperature as measured by the temperature sensor 208. Subsequent to startup, the DCXO controller 202 controls the DCXO circuit 210 to operate in accordance with fine tuning data received via the transceiver 204 and/or temperature data provided by the temperature sensor 208. The DCXO controller 202 stores the new fine tuning data in the memory 206 in association with the current temperature for use in subsequent startup operations. In this manner, the values stored in the memory 206 are adjusted over time to reflect changes in the DCXO circuit 210 and/or the oscillator 212, thereby ensuring the frequency offset remains at a desired level at startup prior to fine tuning.

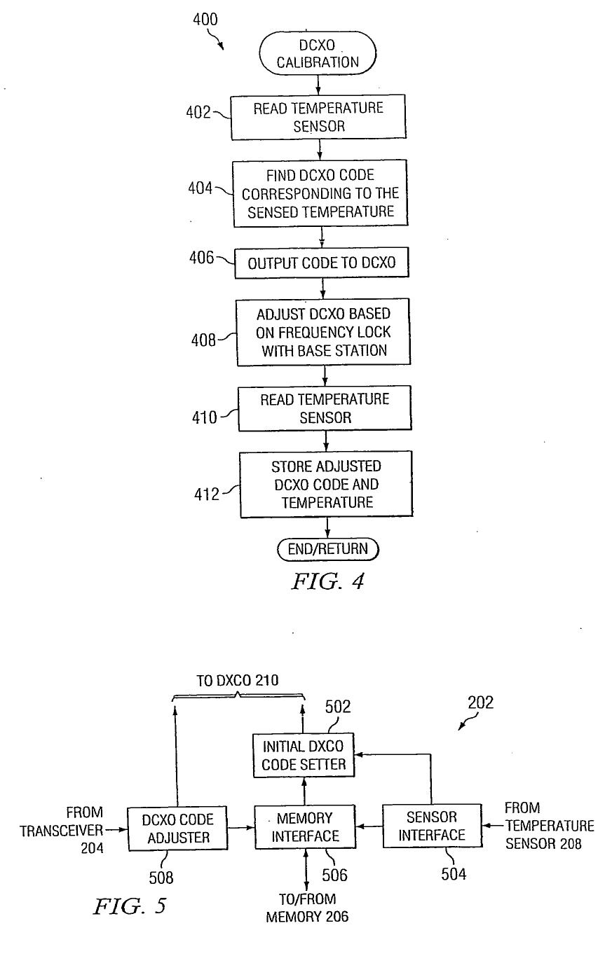

In more detail, the DCXO controller 202 may be implemented by any combination of hardware, firmware, and/or software. For example, the DCXO controller 202 may be implemented in hardware as an application specific integrated circuit (ASIC), either as a stand-alone device or as a portion of a larger device including a significant number of systems and circuits. Alternatively, the DCXO controller 202 may be implemented as software or firmware code executed by a microcontroller or a microprocessor. For example, the DCXO controller 202 may be a generic microprocessor or microcontroller, and software and/or firmware may be stored in the memory 206 and loaded by the microcontroller or microprocessor at power up or some other time to implement the functionality of the DCXO controller 202. Of course, in such an arrangement, the microcontroller or microprocessor may be used to implement other functions or perform other activities in addition to those performed by the DCXO controller 202. More specific examples of the DCXO controller 202 as implemented in software/firmware code and as hardware functional blocks are described in conjunction with FIGS. 4 and 5, respectively.

The transceiver 204, which may include a receiver portion that receives RF signals from an antenna 214, may be implemented using hardware, software, firmware, or any suitable combination thereof The transceiver 204, regardless of its specific configuration, receives and processes RF signals provided by infrastructure (e.g., the infrastructure 104 of FIG. 1). As will be readily appreciated by those having ordinary skill in the art, the transceiver 204 may be coupled to systems other than the system 200 to provide received communications thereto. In the system 200 of FIG. 2, the transceiver 204 passes frequency control messages to the DCXO controller 202 to enable the DCXO controller 202 to fine tune the resonant frequency of the oscillator 212 via the DCXO circuit 210. The transceiver 204 may also include a transmitter portion for sending information.

The transceiver 204 may also be coupled to other circuits and components 218, which may include transmit and/or receive circuitry, audio circuitry such as an earpiece speaker and/or a microphone. For example, a microphone may be coupled to the transceiver 204 so that a user's voice may be converted into electrical signals and transmitted. Similarly, the transceiver 204 may provide received audio to an earpiece speaker so that a user may hear audio.

The memory 206 may be implemented using any suitable memory device or technology. For example, the memory 206 may be implemented using non-volatile memory such as flash memory. Alternatively, the memory 206 may be composed of any number of different memory technologies. The memory 206 may be an individual device or may be integrated with the DCXO controller 202. Further, the memory 206 may be exclusively dedicated to DCXO functionality or may be shared with other systems and circuits.

As shown in FIG. 2, the memory 206 stores a lookup table 220 including a number of temperature entries and corresponding DXCO codes. Depending on the size of the memory 206 (e.g., storage capacity) and system constraints, the lookup table 220 may include few entries or many entries.

The temperature sensor 208 may be implemented by any suitable temperature sensing device configured to sense the temperature of the oscillator 212, or at least the ambient temperature thereof. For example, the temperature sensor 208 could be implemented using a positive temperature coefficient (PTC) or negative temperature coefficient (NTC) thermistor, an infrared sensor, or any other suitable device. The temperature sensor 208 may be located proximate the oscillator 212 so that the temperature of the oscillator 212 may be provided to the DCXO controller 202.

As will be readily appreciated, the indication of the temperature to the DCXO controller 202 may be provided in an analog or a digital format. For example, the temperature sensor 208 may output an analog voltage corresponding to the sensed temperature. Alternatively, the temperature sensor 208 may include circuitry that produces digital bits or bytes representative of the sensed temperature. In either case, the DCXO controller 202 receives the temperature indication and processes the same. For example, the DCXO controller 202 may include an on-board analog-to-digital converter that samples analog temperature signals from the temperature sensor 208, or may include a bus or register for receiving a digital temperature indication.

The DCXO circuit 210 responds to the DCXO codes output from the DCXO controller 202 to alter the resonant frequency of the oscillator 212. Further detail of one example implementation of a DCXO circuit 210 is shown in FIG. 3. The example DCXO circuit 210 includes a signal source 302 coupled in parallel with the oscillator 212 and a fixed loading capacitor 304. The example DCXO circuit 210 also includes a variable loading capacitor 306 that is responsive to signals from the DCXO controller 202 to alter its capacitance and thereby alter the resonant frequency of the oscillator 212. The variable loading capacitor 306 may be implemented by a semiconductor capacitor array including individual capacitors that may be digitally controlled (e.g., digitally switched into and out of the resonant circuit) to change the total capacitance value used to load the oscillator 212. Alternatively, the variable loading capacitor 306 may be implemented using semiconductor varactor diodes. In such an arrangement a digital-to-analog controller may be used to convert the digital tuning code to an analog voltage that is used to control the varactor diodes by variably reverse biasing the varactor diodes to affect a desired capacitance change.

The example DCXO circuit 210 also includes an output buffer 308 from which the output frequency (Fout) is taken. The output frequency may be connected to various other systems and circuits. The frequency of the signal from the output buffer 308 is substantially identical to the resonant frequency of the oscillator 212. However, the output buffer 308 prevents any other circuits from substantially affecting the resonant frequency of the oscillator 212 by providing isolation (e.g., a high impedance load) to the oscillator 212.

While the DCXO circuit 210 of FIG. 3 is shown as being a primarily capacitive circuit, it will be readily appreciated by those having ordinary skill in the art that other DCXO circuit implementations may include inductive components in addition to, or in place of, the capacitive component(s) of FIG. 3. Additionally, other topologies of DCXO circuits may be used. Thus, the DCXO circuit 210 may be implemented by any circuit including a variable or programmable reactive (i.e., capacitive and/or inductive) load coupled to the oscillator 212.

The oscillator 212 may be implemented using any suitable oscillator. For example, the oscillator 212 may be a crystal oscillator, a ceramic resonator, or any other type of device that resonates at a particular frequency when a voltage is applied thereto. The oscillator 212 should be capable of being loaded to change its resonant frequency so that the DCXO circuit 210 can vary a reactive load in the resonant circuit to affect the operating frequency of the oscillator 212. The oscillator 212 may have a resonant frequency in any suitable range, such as, for example, 1 MHz to 300 MHz.

A process that may be performed by the DCXO controller 202 is shown in FIG. 4. In an example implementation, firmware or software instructions stored in the memory 206 may be retrieved and executed by a processor or controller that performs the DCXO process 400 to implement to the DCXO controller 202. Alternatively, the DCXO process 400 may be implemented by dedicated hardware blocks that form the DCXO controller 202, or could be implemented using a combination of hardware, software, and/or firmware.

The illustrated DCXO process 400 begins operation by reading a temperature sensor (e.g., the temperature sensor 208 of FIG. 2) (block 402) to determine the temperature of the oscillator (e.g., the oscillator 212 of FIG. 2). The process 400 then searches a lookup table, such as the lookup table 220 stored in memory 206, to determine the DCXO code corresponding to the sensed temperature (block 404) and outputs the DCXO code to the DCXO circuit (e.g., the DCXO circuit 210 of FIG. 2) (block 406). In practice, the process 400 may select the temperature nearest the sensed temperature. For example, a manufacturer may have provided initial lookup table entries of DCXO codes corresponding to sensed temperatures so that the DCXO codes minimize the frequency offset of the oscillator 212.

To this point, a DCXO code has been selected from the memory 206 based on temperature and used to minimize the offset of the oscillator 212. Once the DCXO code is output, the device in which the oscillator is located (e.g., the mobile unit 102) establishes communications with infrastructure (e.g., the infrastructure 104). As part of establishing communication with the infrastructure, the infrastructure will, in a known manner, provide the DXCO controller 202 with a frequency indication, such as a FCB, which is described above. Based on the FCB, the DXCO controller 202 will, in a known manner, adjust the DCXO code to lock the frequency of the mobile unit with the frequency of the infrastructure (block 408). For example, the DCXO controller 202 will vary the reactive load in the DCXO circuit 210 to move the resonating frequency of the oscillator 212 to the frequency dictated by the frequency indication (e.g., the FCB).

To take advantage of the adjusted DCXO code used to synchronize the oscillator frequency with the infrastructure frequency, the process 400 reads the temperature sensor (block 410) to determine the latest temperature of the oscillator (i.e., the temperature most closely corresponding to the adjusted DCXO code). Subsequently, the process 400 stores the adjusted DCXO code in association with the sensed temperature (block 412). For example, the adjusted DCXO code and the sensed temperature may be stored in the lookup table 220 residing in the memory 206. After the adjusted DCXO code is stored, the process 400 ends or returns control to its calling routine.

Storing the adjusted DCXO code in association with the temperature to which the code corresponds enables the DCXO controller 202 to more accurately attempt initial calibration of the oscillator 212 at a subsequent point in time. For example, over time the DCXO code for 25° C. may increase due to aging, but this increase will be reflected in the lookup table 220. Accordingly, in the initial calibration procedure described above in conjunction with blocks 402-406, the DCXO code read from the lookup table 220 for 25° C. will be the adjusted DCXO code. Therefore, the initial calibration of the oscillator 212 (i.e., the calibration that takes place before infrastructure communication is established) is more accurate and has a lower frequency offset.

Of course, modifications to the process 400 may be made. For example, depending on the time between the initial temperature sensor reading and the storage of the adjusted DCXO code in the memory 206, a second temperature sensor reading (block 410) may be omitted. In particular, if there is little time and/or little reason for the temperature of the oscillator 212 to change during the period of time between the initial temperature reading and the time at which the adjusted DCXO code is generated, there would typically be no need to read the temperature a second time.

An example implementation of a DCXO controller 202 is shown in FIG. 5. The DCXO controller 202 may be implemented in hardware and/or software or any combination thereof. On initial power up of the device in which the DCXO controller 202 is located, an initial DCXO code setter 502 reads the oscillator temperature via a sensor interface 504. After the temperature is read, the initial DCXO code setter 502 accesses the memory 206 through a memory interface 506 to retrieve a DCXO code corresponding to the temperature in memory 206 that is closest to the sensed temperature. The initial DCXO code setter 502 then outputs the retrieved DCXO code to the DCXO to implement the oscillator tuning.

After communication is established with another entity (e.g., with infrastructure 104), the DCXO controller 202 receives a frequency indication, such as an FCB. A DCXO code adjuster 508 then determines an adjusted DCXO code that is output to the DCXO to adjust the oscillator frequency. Subsequently, the DXCO code adjuster 508 provides the adjusted DCXO code to the memory interface 506 so that the adjusted DCXO code may be stored in memory 206. The memory interface 506 may also read the sensor interface 504 to determine the current oscillator temperature, which will be stored in association with the adjusted DCXO code.

Although certain methods and apparatus constructed in accordance with the teachings of the invention have been described herein, the scope of coverage of this patent is not limited thereto. On the contrary, this patent covers every apparatus, method and article of manufacture fairly falling within the scope of the appended claims either literally or under the doctrine of equivalents.

1. A method of adjusting an oscillator frequency, comprising:
reading a temperature associated with an oscillator;
reading a first tuning code associated with the temperature from a memory;
tuning the oscillator with the first tuning code;
determining a second tuning code; and
storing the second tuning code and an indication of the temperature in the memory.

2. A method as defined by claim 1, further comprising tuning the oscillator with the second tuning code.

3. A method as defined by claim 1, wherein tuning the oscillator with the first tuning code comprises changing a reactive load on the oscillator.

4. A method as defined by claim 1, wherein the temperature is a first temperature, and further comprising reading a second temperature associated with the oscillator and storing the second temperature is association with the second tuning code in the memory.

5. A method as defined by claim 1, wherein determining the second tuning code comprises:
receiving a frequency indication; and
determining the second tuning code based on the frequency indication.

6. A method as defined by claim 5, further comprising establishing communication with another entity and receiving the frequency indication therefrom.

7. A method as defined by claim 1, further comprising reading the second tuning code from the memory and tuning the oscillator with the second tuning code.

8. A method as defined by claim 1, wherein storing the second tuning code and the indication of the temperature in the memory comprises storing the second tuning code and the indication of the temperature in a lookup table including a plurality of temperatures and a plurality of corresponding tuning codes.

9. A frequency control system comprising:
an oscillator;
an adjustable reactive load coupled to the oscillator;
a temperature sensor adapted to sense a temperature associated with the oscillator;
a memory; and
a controller coupled to the adjustable reactive load, the temperature sensor, and the memory, the controller configured to:
read a temperature associated with the oscillator;
read a first tuning code associated with the temperature from the memory;
tune the oscillator with the first tuning code;
determine a second tuning code; and
store the second tuning code and an indication of the temperature in the memory.

10. A system defined by claim 9, wherein the oscillator comprises one of a crystal oscillator and a resonator.

11. A system defined by claim 9, wherein the memory comprises non-volatile memory.

12. A system defined by claim 9, further comprising a receiver coupled to the controller and configured to provide the controller with a frequency indication.

13. A system defined by claim 12, wherein the frequency indication comprises a frequency control burst.

14. A system defined by claim 12, wherein the controller is configured to determine the second tuning code based on the frequency indication.

15. A system defined by claim 9, wherein the memory stores a lookup table including a plurality of temperatures and a plurality of corresponding tuning codes.

16. A machine-accessible medium having a plurality of machine accessible instructions that, when executed, cause a machine to:
read a temperature associated with an oscillator;
read a first tuning code associated with the temperature from a memory;
tune the oscillator with the first tuning code;
determine a second tuning code; and
store the second tuning code and an indication of the temperature in the memory.

17. A machine-accessible medium as defined by claim 16, further comprising instructions that, when executed, cause the machine to tune the oscillator with the second tuning code.

18. A machine-accessible medium as defined by claim 16, wherein the memory comprises flash memory.

19. A machine-accessible medium as defined by claim 18, wherein the memory comprises a lookup table including a plurality of temperatures and a plurality of tuning codes.

20. A machine-accessible medium as defined by claim 16, further comprising instructions that, when executed, cause the machine to:
receive a frequency indication; and
determine the second tuning code based on the frequency indication.

21. A controller for adjusting an oscillator frequency comprising:
a memory;
a sensor interface to receive a temperature value;
an initial DCXO code setter to access the memory to retrieve a first DCXO code based on the temperature value; and
a DCXO code adjuster to generate a second DCXO code based on frequency data received from an external device, and to store the second DCXO code in the memory.

22. A controller as defined by claim 21, wherein the DCXO code adjuster tunes an oscillator by outputting the first DCXO code to a reactive load coupled to the oscillator.

23. A controller as defined by claim 21, wherein the memory comprises a lookup table including a plurality of temperatures and a plurality of corresponding tuning codes.
